(19) United States
(12) Patent Application Publication
(10) Pub. No.: US 2003/0089992 A1
(43) Pub. Date: May 15, 2003

(54) SILICON CARBIDE DEPOSITION FOR USE AS A BARRIER LAYER AND AN ETCH STOP

(76) Inventors: SUDHA RATHI, SAN JOSE, CA (US); PING XU, CUPERTINO, CA (US); CHRISTOPHER BENCHER, SUNNYVALE, CA (US); JUDY HUANG, LOS GATOS, CA (US); KEGANG HUANG, FREMONT, CA (US); CHRIS NGAI, BURLINGAME, CA (US)

Correspondence Address: APPLIED MATERIALS, INC., 2881 SCOTT BLVD. M/S 2061, SANTA CLARA, CA, 95050, US

(21) Appl. No.: 09/165,248

(22) Filed: Oct. 1, 1998

(51) Int. Cl. H01L 21/4763; H01L 21/44; H01L 21/31; H01L 21/469; H01L 23/48; H01L 23/52; H01L 29/40

(52) U.S. Cl. 257/762; 438/633; 438/634; 438/687; 438/778; 257/767

(57) ABSTRACT

The present invention generally provides an improved process for depositing silicon carbide, using a silane-based material with certain process parameters, onto an electronic device, such as a semiconductor, that is useful for forming a suitable barrier layer, an etch stop, and a passivation layer for IC applications. As a barrier layer, in the preferred embodiment, the particular silicon carbide material is used to reduce the diffusion of copper and may also used to minimize the contribution of the barrier layer to the capacitive coupling between interconnect lines. It may also be used as an etch stop, for instance, below an intermetal dielectric (IMD) and especially if the IMD is a low k, silane-based IMD. In another embodiment, it may be used to provide a passivation layer, resistant to moisture and other adverse ambient conditions. Each of these aspects may be used in a dual damascene structure.

### FIELD OF THE INVENTION

The present invention relates generally to the fabrication of integrated circuits on substrates. More particularly, the invention relates to a low temperature method for producing a silicon carbide film utilizing alkyl silanes under certain process regimes, which may be useful as a barrier layer, etch stop, and passivation layer.

### BACKGROUND OF THE INVENTION

Consistent and fairly predictable improvement in integrated circuit design and fabrication has been observed in the last decade. One key to successful improvements is the multilevel interconnect technology, which provides the conductive paths between the devices of an integrated circuit (IC) device. The shrinking dimensions of features, presently in the sub-quarter micron and smaller range, such as horizontal interconnects (typically referred to as lines) and vertical interconnects (typically referred to as contacts or vias; contacts extend to a device on the underlying substrate, while vias extend to an underlying metal layer, such as M1, M2, etc.) in very large scale integration (VLSI) and ultra large scale integration (ULSI) technology, has increased the importance of reducing capacitive coupling between interconnect lines in particular. In order to further improve the speed of semiconductor devices on integrated circuits, it has become necessary to use conductive materials having low resistivity and low k (dielectric constant less than 4.0) insulators to reduce the capacitive coupling between adjacent metal lines. However, typical low k dielectric materials are generally porous and require a barrier layer. However, typical barrier layer materials have dielectric constants that are significantly greater than 7.0 that result in a combined insulator that does not significantly reduce the dielectric constant.

Furthermore, the decreasing feature size has created a need for using a conductive material with greater conductivity. Aluminum has been the choice for some time. However, because of the decrease in feature sizes, copper (Cu) is now being considered as an interconnect material in place of aluminum, because copper has a lower resistivity (1.7 μΩ-cm compared to 3.1 μΩ-cm for aluminum) and higher current carrying capacity. However, copper has its own difficulties for IC manufacturing processes. For instance, copper diffuses more readily into surrounding materials and hence requires better materials for a barrier layer than traditionally has been used for aluminum. This greater diffusion characteristic exacerbates the low k porosity described above and places ever greater emphasis upon the quality of the barrier layers.

Adding to the difficulties of low k materials and copper diffusion is the difficulty of obtaining precise pattern etching with copper, using traditional deposition/etch processes for forming interconnects. Thus, new and more complicated processes are being developed, such as a dual damascene structure for forming copper interconnects. In a dual damascene structure, the dielectric layer is etched to define both the contacts/vias and the interconnect lines. Metal is then inlaid into the defined pattern and any excess metal is removed from the top of the structure in a planarization process, such as chemical mechanical polishing (CMP).

FIG. 1 shows one example of a dual damascene structure. The integrated circuit 10 includes an underlying substrate 12, which may include a series of layers deposited thereon. In this patent, “substrate” is used to indicate an underlying material, and can be used to represent a series of underlying layers below the layer in question, such as a copper barrier. A barrier layer 13 may be deposited over the substrate, followed by a dielectric layer 14. The dielectric layer may be un-doped silicon dioxide also known as un-doped silicon glass (USG), fluorine-doped silicon glass (FSG), or some other low k material. An etch stop layer 16 is deposited, pattern etched, and followed by another dielectric layer 18. The structure is again pattern etched to produce a damascene type pattern. A barrier layer 22 may be needed, which typically has been made from Ta, TaN, Ti, TiN, and other materials, prior to the present invention. However, as explained above, with the smaller feature sizes and increased diffusion propensity of copper, the prior barrier layer materials are inadequate for optimal performance. Once the conductive material 20 has filled the features, another layer 24, such as a passivation layer, may be deposited. This structure is exemplary for a dual damascene structure and others may be more appropriate for the particular application.

Thus, with the decreasing feature sizes, the low k needs, the use of copper, and the complex dual damascene structures, new methods and materials are needed to provide improved barrier, etch stop, and passivation characteristics. Silicon nitride has been the etch stop material of choice and used for various overlays, including passivation layers. However, silicon nitride has a relatively high dielectric constant (dielectric constant greater than 7.0) and may significantly increase the capacitive coupling between interconnect lines. This may lead to cross talk and/or resistance-capacitance (RC) delay, i.e., the time required to dissipate stored energy, that degrades the overall performance of the device. Additionally, silicon nitride has relatively poor diffusion resistance compared to the material of the present invention.

In searching for new materials, others have recognized some potential in silicon carbide (SiC). But to the knowledge of the inventors, no source has adequately sought and developed a suitable barrier, etch stop, and passivation layer using SiC, and certainly not a SiC material deposited according to the process regimes disclosed herein. One such reference is U.S. Pat. No. 4,532,150 to Endo et al., which is incorporated by reference, wherein Endo refers to a specific formulation of SiₓC₁₋ₓ in which x is a positive number of 0.2 to 0.9 for providing SiC to a substrate surface. Endo provides no disclosure of SiC as a barrier, etch stop, or passivation layer, and the process parameters given in its examples are below the preferred or most preferred parameters of the present invention. U.S. Pat. No. 5,465,680 to Loboda, incorporated by reference, discloses a SiC film in a CVD chamber, but fails to produce the film at low temperatures by requiring about 600° to 1000° C. and above. Another reference, U.S. Pat. No. 5,238,866 to Bolz et al., also incorporated by reference, uses methane, silane, and phosphine to create a hydrogenated silicon carbide coating for use in the medical field, having an improved compatibility with blood. However, none of these references contain a disclosure for SiC with the following process regimes used as a barrier layer and etch stop layer.

Therefore, there is a need for an improved process using silicon carbide as a barrier layer, an etch stop, and a passivation layer for ICs.

### SUMMARY OF THE INVENTION

The present invention generally provides an improved process for depositing silicon carbide, using a silane-based material with certain process parameters, onto an electronic device, such as a semiconductor, that is useful for forming a suitable barrier layer, an etch stop, and a passivation layer for IC applications. As a barrier layer, in the preferred embodiment, the particular silicon carbide material is used to reduce the diffusion of copper and may also used to minimize the contribution of the barrier layer to the capacitive coupling between interconnect lines. It may also be used as an etch stop, for instance, below an intermetal dielectric (IMD) and especially if the IMD is a low k, silane-based IMD. In another embodiment, it may be used to provide a passivation layer, resistant to moisture and other adverse ambient conditions. Each of these aspects may be used in a dual damascene structure.

A preferred process sequence for forming a silicon carbide barrier layer on a substrate, comprises introducing silicon, carbon, and a noble gas into a reaction zone of a process chamber, initiating a plasma in the reaction zone, reacting the silicon and the carbon in the presence of the plasma to form silicon carbide, and depositing a silicon carbide barrier layer on a substrate in the chamber. Another sequence comprises introducing silicon, carbon, and a noble gas in a reaction zone of a chamber, initiating a plasma in the reaction zone, reacting the silicon and the carbon in the presence of the plasma to form silicon carbide, and depositing a silicon carbide passivation layer on the substrate. Still another aspect may include a substrate having a silicon carbide barrier layer, comprising a semiconductor substrate, a dielectric layer deposited on the substrate, and a silicon carbide barrier layer having a dielectric constant of about 6 or less.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 shows a schematic of an exemplary damascene structure.

FIG. 2 shows a FTIR of the SiC of the present invention, indicating a particular bonding structure.

FIG. 3 shows a FTIR of a previous SiC, indicating a bonding structure different than the SiC of the present invention.

FIG. 4 shows a schematic of a multi-layered substrate.

FIG. 5 shows a graph of copper diffusion into a SiC barrier layer, where the barrier layer was deposited with a plasma enhanced chemical vapor deposition process.

FIG. 6 shows a transmission electron microscopy photograph of the SiC of the present invention, used as an etch stop.

FIG. 7 shows a transmission electron microscopy photograph of the SiC of the present invention, used as a passivation layer.

### DETAILED DESCRIPTION OF A PREFERRED EMBODIMENT

The present invention provides a SiC material, formed according to certain process regimes, useful as a barrier layer and/or etch stop for an integrated circuit, and particularly for an integrated circuit using copper as a conductive material. The invention also provides processing regimes that includes using a silane-based compound for a silicon source in some embodiments and a methylsilane as a silicon and carbon source, perhaps independently of any other carbon source and perhaps in the absence of a substantial amount of oxygen. The process regimes also include the presence of a noble gas, such as helium or argon, and certain temperatures, pressures, power outputs in a plasma enhanced chemical vapor deposition chamber to produce the SiC of the present invention. By adjusting the parameters, the silicon carbide layer may also be used as a passivation layer. This particular SiC material may be especially useful in complex structures, such as a damascene structure.

Chart 1 shows some of the general requirements for a barrier layer and/or an etch stop using copper as a conductive material, although other conductors may be applicable.

DESIRABLE CHARACTERISTICS OF DIELECTRIC BARRIER/ETCH STOP

| | |
|---|---|
| Good Barrier Property to Copper | Good Adhesion |
| | No Copper Diffusion at 400°-450° C. |
| | Annealing Stage |
| High Etch Selectivity with respect | Etch Stop >40:1 |
| to USG/FSG/Other Low k Dielectric Materials | |
| Lower Dielectric Constant | Overall Reduction in Effective |
| | Dielectric Constant (K_{eff}) in IMD |
| | Damascene Stacks |
| Good Electrical Properties | High Breakdown Voltage |
| | Low Leakage |
| Productivity/Manufacturability | Process Stability and Particle Control |
| | In-situ Process for Throughput |
| | Improvement, e.g., USG Deposition |
| | with Etch Stop Layer Deposition |

Referring to Chart 1, adhesion between the layers is important to reduce delamination between the layers and, in some instances, to reduce capacitance and resistance between the layers. The material should also have no substantial diffusion at a substrate annealing temperature of, for example, 400°-450° C. The term “no substantial” diffusion is intended to be a functional term, such that any actual diffusion into the layer is less than would affect the ability of the layer to function as a barrier layer and/or etch stop. For instance, the SiC of the present invention limits the diffusion to about 250 Å. The copper diffusion may impair the desired current and voltage paths and contribute to cross-talk. Because of the decreasing feature size, as described above, the lower the dielectric constant, preferably less than 7.0, the lower the probability for cross talk and RC delay which degrades the overall performance of the device. Related to the low dielectric value is the “effective” dielectric constant, which is a value found by multiplying the dielectric constant times the thickness of the layer, where a desirable value should be 3.0 or less. Because the barrier layer may be used in a damascene structure, it would be beneficial to also have suitable etch stop characteristics, such as an etch selectivity ratio of 40 to 1 or greater with respect to USG, FSG, or other low k dielectric materials. Additionally, the material should have a high breakdown voltage of 2 MV or more, i.e., the voltage gradient at which the molecules breakdown to allow harmful passage of electrical current. It should also have a low leakage through the layer, i.e., a low stray direct current that capacitively flows through the material. Another desired characteristic from a commercial standpoint is that the material should be compatible with other processes, so the processes may be performed in situ, i.e., in a given chamber, such as in a plasma chamber, or in a system, such as an integrated cluster tool arrangement, without exposing the material to contamination environments, to produce better throughput and process control. This aspect may be particularly important with copper, because of its rapid susceptibility to oxidation.

Table 1 shows the process parameters of the present invention used in a 200 mm wafer chamber that allows the SiC material to be used as a barrier/etch stop and a passivation layer. In the embodiments tested, the silicon and carbon were derived from a common compound, such as a silane-based compound. However, the carbon could be supplemented with other compounds, such as methane. Without limitation, suitable silane-based compounds could include: methylsilane (CH₃SiH₃), dimethysilane ((CH₃)₂SiH₂), trimethylsilane ((CH₃)₃SiH), diethylsilane ((C₂H₅)₂SiH₂), propylsilane (C₃H₈SiH₃), vinyl methylsilane (CH₂═CH)CH₃SiH₂), 1, 1, 2, 2-tetramethyl disilane (HSi(CH₃)₂—Si(CH₃)₂H), hexamethyl disilane ((CH₃)₃Si—Si(CH₃)₃), 1, 1, 2, 2, 3, 3-hexamethyl trisilane (H(CH₃)₂Si—Si(CH₃)₂—SiH(CH₃)₂), 1, 1, 2, 3, 3-pentamethyl trisilane (H(CH₃)₂Si—SiH(CH₃)—SiH(CH₃)₂), and other silane related compounds. For the purposes of this invention, the term “methylsilane” as used herein includes any silane-based compound having at least one carbon atom attached, including the preceding list, unless otherwise indicated. In Table 1, the compounds used were trimethylsilane and methylsilane. A noble gas, such as helium or argon, was present and may assist in stabilizing the process, although other gases could be used.

TABLE 1

| | Barrier/Etch Stop | | | Passivation | | |
|---|---|---|---|---|---|---|
| Parameter | Range | Preferred | Most Pref. | Range | Preferred | Most Pref. |
| Silicon (3MS or | 10-1000 | 30-500 | 50-200 | 10-1000 | 100-500 | 200-400 |
| MS-sccm) | | | | | | |
| Carbon (3MS or | above | above | above | above | above | above |
| MS-sccm) | | | | | | |
| Noble (He or Ar- | 50-5000 | 100- | 200-1000 | 100-5000 | 1000- | 1200- |
| sccm) | | 2000 | | | 2000 | 1700 |
| Press. (Torr) | 1-12 | 3-10 | 6-10 | 1-9 | 6-8 | 6-8 |
| RF Power (Watts) | 100- | 300-700 | 400-600 | 100-1000 | 600-1000 | 700-900 |
| | 1000 | | | | | |
| Power Density | 0.7-14.3 | 4.3-10.0 | 5.7-8.6 | 0.7-14.3 | 8.6-14.3 | 10.0- |
| (Watts/cm²) | | | | | | 12.9 |
| Freq. (MHz) | 13.56 | 13.56 | 13.56 | 13.56 | 13.56 | 13.56 |
| Temp. (C) | 100-450 | 200-400 | 300-400 | 100-450 | 200-400 | 300-400 |
| Spacing (Mils) | 200-600 | 300-600 | 300-500 | 200-600 | 200-600 | 300-500 |

### EXAMPLE 1

### Barrier/Etch Stop Layer

The inventors have discovered that the process regime described below establishes the suitability of the SiC material in meeting the desired criteria of a barrier layer and/or etch stop. Using the process regimes, the SiC can have a low dielectric constant of about 6.0 or less. Importantly, the SiC barrier properties described herein enable a thinner layer to be deposited. Thus, an effective SiC dielectric constant of the present invention may be about 3.0 or less. This effective dielectric constant meets the needs of a suitable copper-based IC and contrasts with silicon nitride material described above. Furthermore, the SiC material of the present invention has a high resistance to copper diffusion with test data showing that the copper diffusion limit is about 200 to 250 Å deep in the barrier layer. This particular SiC material also is suitable for use as a low k, etch stop material. A low k etch stop material is defined herein as an etch stop material having a dielectric constant equal to or lower than that of silicon nitride (dielectric constant of greater than or equal to 7.0) and having a relative oxide to etch selectivity of 40 to 1 or greater when used in conjunction with a silicone-based dielectric. This ratio allows greater control over the etching process and is particularly useful when etching complex structures, such as a damascene structure.

To create a barrier layer and/or etch stop in the preferred process regimes, a silicon source such as trimethylsilane or methylsilane may be supplied to a plasma reactor, specifically a reaction zone in the chamber that is typically between the substrate surface and the gas dispersion element, such as a “showerhead”, commonly known to those with ordinary skill in the art. For a typical commercial plasma enhanced chemical vapor deposition (PECVD) chamber such as manufactured by Applied Materials, Inc. of Santa Clara, Calif., a silicon source flow rate of about 30 to 500 standard cubic centimeters (sccm) may be used. The sequence and operation of a commercial PECVD chamber are well known and need no explanation for the present invention process regimes. The carbon may be derived from the trimethylsilane or methylsilane, independent of other carbon sources. The reaction may occur without a substantial source of oxygen introduced into the reaction zone. In conjunction with the silicon and carbon sources, a noble gas, such as helium or argon, may flow into the chamber at a rate of about 100 to 2000 sccm. The chamber pressure is preferably maintained between about 3 to 10 Torr. A single 13.56 MHz RF power source may apply about 300 to 700 watts with a power density of about 4.3 to 10 watts/cm² to the anode and cathode to form the plasma in the chamber with the silane-based gas. The substrate surface temperature may be maintained between about 200° to 400° C., during the deposition of the barrier layer and/or etch stop. The gas dispersion from a gas dispersion element, such as a “showerhead”, may be dispersed at a showerhead to substrate spacing distance between about 300 to 600 mils.

For a more optimal, designated “most preferred,” process regime, the trimethylsilane or methylsilane flow rate may be adjusted to about 50 to 200 sccm, the helium or argon flow rate to about 200 to 1000 sccm, the chamber pressure to about 6 to 10 Torr, the RF power to about 400 to 600 watts with a power density of about 5.7 to 8.6 watts/cm², the substrate surface temperature maintained between about 300° to 400° C., and a showerhead to substrate spacing of about 300 to 400 mils, as shown in Table 1.

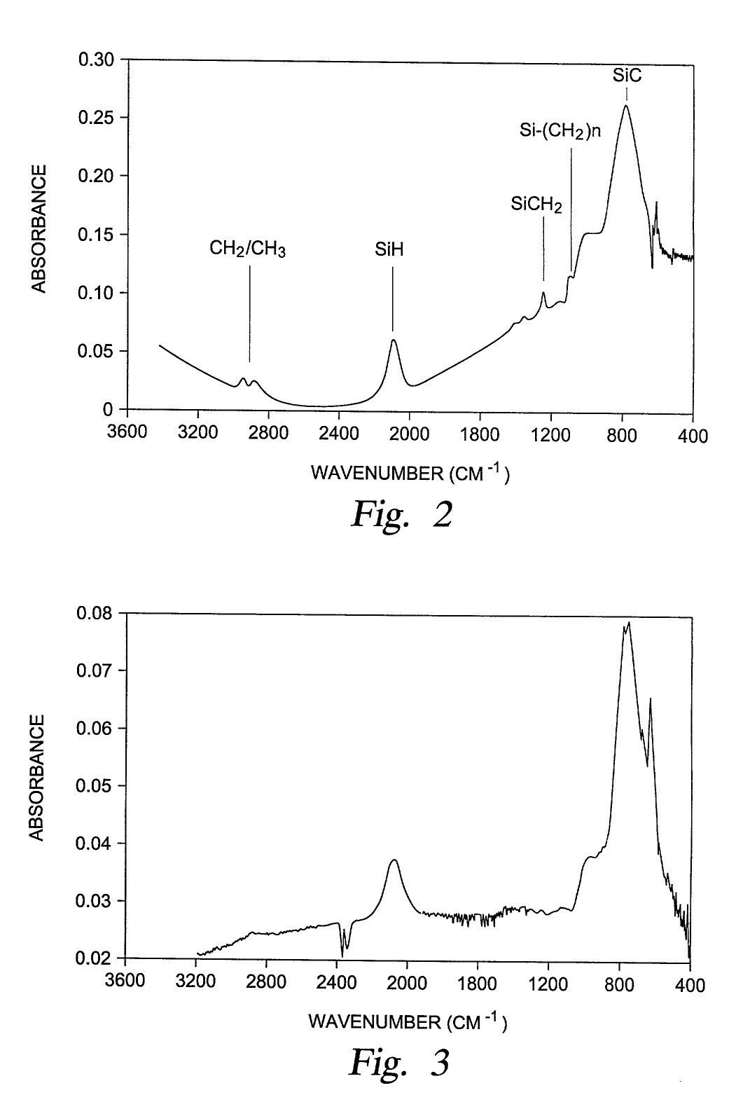

The characteristics developed by the preferred and most preferred process regimes differ from the generally accepted silicon carbide characteristics. At these parameters, a different bonding structure occurs in the SiC of the present invention, shown in FIG. 2 compared to a prior SiC, shown in FIG. 3. The charts are Fourier Transform Infrared (FTIR) charts, one of the standard laboratory tests for indicating the bonding structure, as would be known to those with ordinary skill in the art and needs no detailed explanation. The various peaks at various wave numbers are structure specific and this graph is indicative of the particular interstitial bonding structure.

FIG. 2 shows a FTIR for the SiC of the present invention. Using the most preferred range of process parameters of Table 1 with trimethylsilane, the deposition resulted in a bonding structure containing CH₂/CH₃, SiH, SiCH₃, Si—(CH₂)n, and SiC. FIG. 3 shows comparative results with a prior SiC material deposited using silane and methane. As can be seen, there is no corresponding peak for Si—(CH₂)n and even the peak for SiCH₃ is not as noticeable. The SiC of the present invention has yielded these unexpected results in providing better barrier layer/etch stop performance than previous known depositions of SiC. These characteristics allow the SiC to be used in the various capacities disclosed herein, including a barrier layer that may or may not be used as an etch stop.

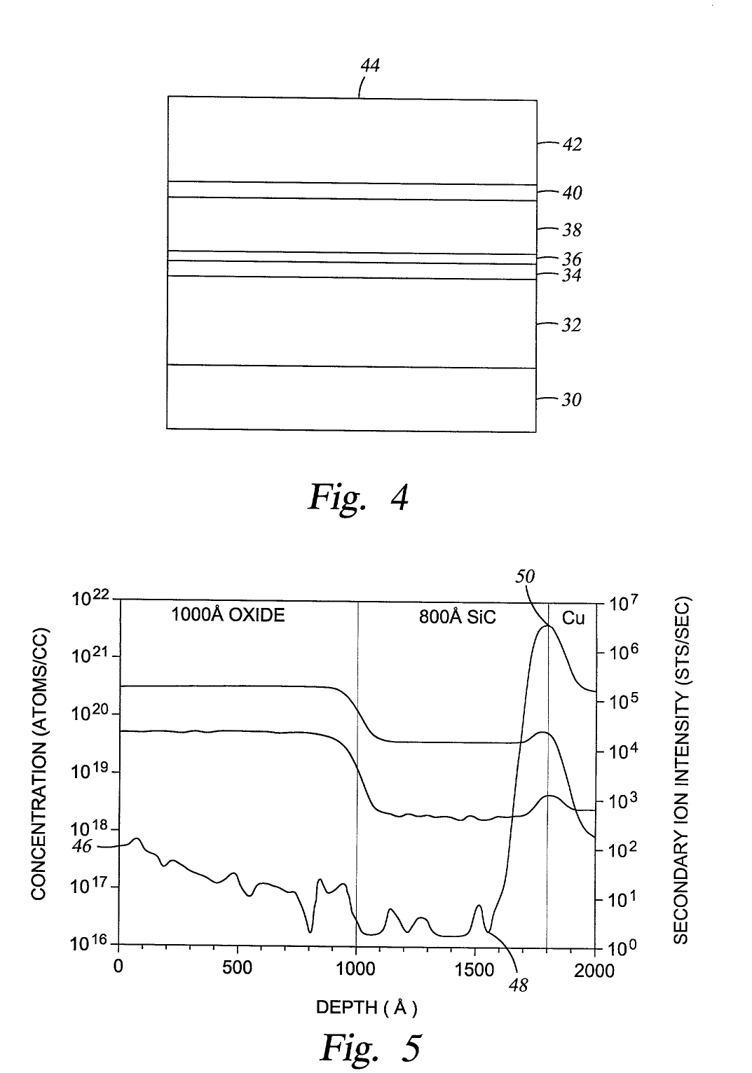

FIGS. 4-6 show charts and aspects of this SiC material used as a barrier layer and/or etch stop. FIG. 4 shows a construction of a multi-layer substrate test specimen, incorporating the SiC of the present invention as a barrier layer and/or etch stop material. In FIG. 4, a 5000 Å thick oxide layer 32 was deposited on the silicon substrate 30, followed by a 800 Å thick SiC barrier layer 34. The SiC barrier layer was created using the most preferred regime and had a dielectric constant of approximately 5 to 6. Next, a TaN barrier layer 36 was deposited on the SiC barrier layer 34, followed by a 5000 Å thick copper layer 38. Next, a 800 Å thick SiC barrier layer 40, formed according to the present invention, was deposited on the copper layer 38, followed by a 1000 Å thick oxide layer 42. The test specimen was then subjected to six annealing cycles with the substrate surface temperature between about 400° to 450° C. in an inert nitrogen atmosphere and the copper diffusion measured. Several annealing cycles were applied to the test specimen to contaminate the barrier layer with diffused copper.

FIG. 5 shows the test specimen diffusion results, where the lower curve shows the copper content. Starting with the y-axis, FIG. 5 shows a value 46 of approximately 3×10¹⁷ atoms per cubic centimeter (atoms/cc) at a depth of 0 Å from the outer surface 44 of FIG. 4. This value reduces to value 48 of about 1×10¹⁶ atoms/cc at a depth of about 1570 Å, before the copper diffusion becomes noticeable. The copper diffusion level then rises logarithmically for the next 230 Å to a value 50 of approximately 3×10²¹ atoms/cc at the copper-copper barrier interface. Thus, the level of copper reduces by approximately four orders of magnitude, i.e., 1/10,000, within about 200 Å to 250 Å of the interface. This decrease in copper diffusion shows the effectiveness of this SiC material.

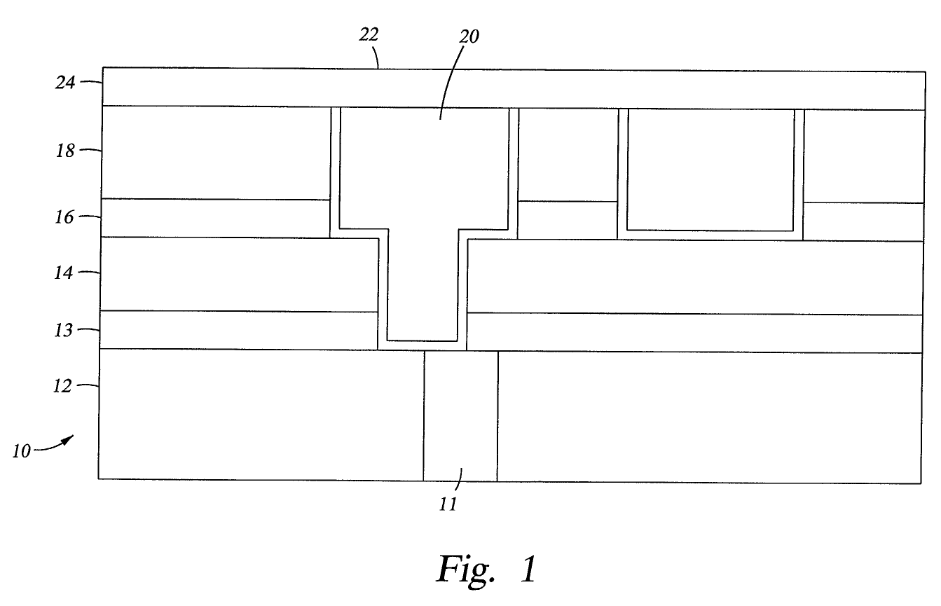

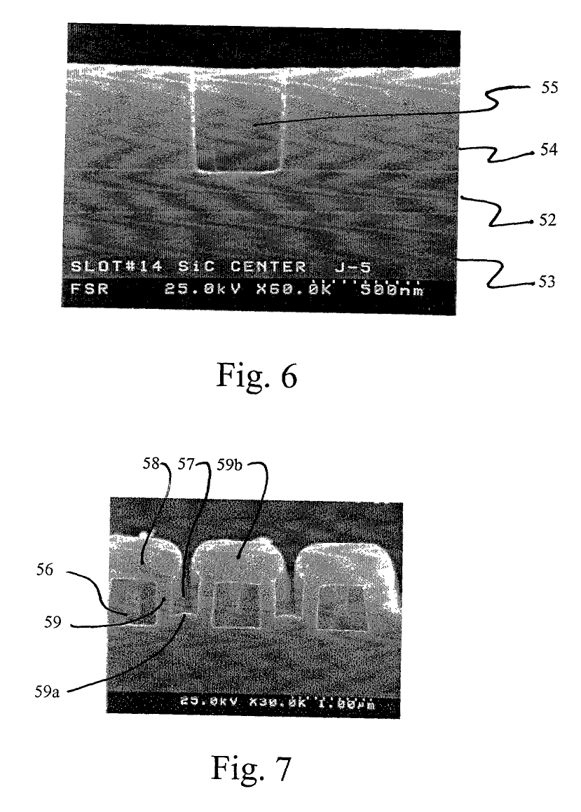

Using the same or similar process regimes, FIG. 6 shows a transmission electron microscopy photograph of this SiC, used as an etch stop. SiC layer 52 corresponds to the etch stop 16 of FIG. 1 in an exemplary embodiment. The underlying dielectric oxide layer 53 was about 1000 Å thick, and the SiC layer 52 was about 1000 Å thick. The SiC layer was deposited using the most preferred barrier layer/etch stop process regime of Table 1. An oxide layer 54 with a 5000 Å thickness was deposited over the SiC layer 52. Using an etching material, that in this case was a dry etch of octafluorocyclobutane (C₄F₈) and Ar, an interconnect 55 was etched through the 5000 Å thick oxide into the SiC material about 100 Å deep or less, using a 150% over etch. The etch selectivity was approximately 40. The SiC of the present invention exhibited etch selectivity without allowing the etching chemical to intrude through or even significantly into the etch stop.

### EXAMPLE 2

### Passivation Layer

In addition to serving as an improved barrier/etch stop layer, the SiC films of the present invention may also be used as a passivation layer. The passivation layer may play an increasingly larger role in copper-based devices, because the copper diffuses into surrounding layers. Furthermore, the silicon carbide material, with some process modifications compared to the most preferred parameters of the barrier/etch stop material, offers good resistance against moisture and other adverse conditions. Moisture resistance is generally rated for no substantial loss or penetration to the underlying film in an environment of 20 psi at 150° C. for a 24 hour period, as would be known to those with ordinary skill in the art.

The parameters for adjusting the process to form a SiC passivation layer are shown in Table 1, as well. In the preferred process regimes, a silicon source, such as trimethylsilane or methylsilane, may flow in the chamber at a rate of about 100 to 500 sccm for a typical commercial PECVD chamber, such as one manufactured by Applied Materials, Inc. The carbon may be derived from the same silane-based compound, such as trimethylsilane or methylsilane, used to obtain the silicon. In conjunction with the silicon and carbon source, a noble gas, such as helium or argon, may also flow into the chamber at a rate of about 1000 to 2000 sccm. The chamber pressure is preferably maintained between about 6 to 8 Torr. A single 13.56 MHz RF power source may apply about 600 to 1000 watts with a power density of about 8.6 to 14.3 watts/cm² to the anode and cathode to form a plasma in the chamber. The substrate temperature may be maintained between about 200° to 400° C. and the showerhead to substrate surface spacing may be between about 200 to 600 mils. For a more optimal, designated “most preferred,” process regime, the trimethylsilane or methylsilane flow rate is between about 200 to 400 sccm, the helium or argon flow rate between about 1200 to 1700 sccm, the chamber pressure maintained between about 6 to 8 Torr, the RF power between about 700 to 900 watts with a power density of about 10.0 to 12.9 watts/cm², the substrate temperature between about 300° to 400° C., and a showerhead to substrate spacing between about 300 to 500 mils, as shown in Table 1.

FIG. 7 shows a transmission electron microscopy photograph of the SiC passivation layer of the present invention. Besides being moisture resistance, one of the desirable characteristics is step coverage to conform to the features. The test specimen features included an Al layer approximately 800 Å thick on an underlying silicon substrate 56, having an interconnect 57 approximately 0.3 to 0.4 μm wide. The test specimen was then etched down to the substrate at about a 800 Å depth, prior to deposition of the passivation layer. As can be seen in the microscopy photographs of FIG. 7, the passivation layer using the SiC of the present invention provides such step coverage. Test results have shown a greater than about 35 percent sidewall 59 coverage and greater than about 45 percent bottom 59a step coverage with open filed step 59b coverage greater than about 65 percent.

The present invention further provides a substrate processing system having a plasma reactor including a chamber, a reaction zone in the chamber, a substrate holder for positioning a substrate in the reaction zone, and a vacuum system. The processing system further comprises a gas/liquid distribution system connecting the reaction zone of the vacuum chamber that supplies an silane-based compound, an inert gas, and an RF generator coupled to the gas distribution system for generating a plasma in the reaction zone. The processing system further includes a controller comprising a computer for controlling the plasma reactor, the gas distribution system, the RF generator, and a memory coupled to the controller, the memory comprising a computer usable medium including a computer readable program code for selecting the process steps for depositing a low dielectric constant film with a plasma of an silane-based compound.

The processing system may further comprise in one embodiment computer readable program code for selecting the process steps for depositing a barrier layer and/or etch stop of the silane-based compound, depositing a different dielectric layer, and optionally depositing a capping passivation layer of the silane-based compound.

While the foregoing is directed to the preferred embodiment of the present invention, other and further embodiments of the invention may be devised without departing from the basic scope thereof, and the scope thereof is determined by the claims which follow.

What is claimed is:

1. A method of forming a silicon carbide barrier layer on a substrate, comprising:
a) introducing silicon, carbon, and a noble gas into a chamber;
b) initiating a plasma in the chamber;
b) reacting the silicon and the carbon in the presence of the plasma to form silicon carbide; and
c) depositing a silicon carbide barrier layer on the substrate in the chamber.

2. A method of claim 1, wherein the silicon comprises a silane.

3. A method of claim 1, wherein the silicon and carbon are derived from a common methylsilane, independent of other carbon sources.

4. A method of claim 1, further comprising depositing the silicon carbide barrier layer at a temperature of between about 100° to about 450° C.

5. A method of claim 1, further comprising depositing the silicon carbide barrier layer at a temperature of between about 300° to about 400° C.

6. A method of claim 1, further comprising producing a silicon carbide barrier layer having a dielectric constant of no greater than about 6.

7. A method of claim 1, further comprising producing a silicon carbide barrier layer having an effective dielectric constant of no greater than about 3.

8. A method of claim 1, further comprising producing a silicon carbide barrier layer which is copper diffusion resistant.

9. A method of claim 1, further comprising producing a silicon carbide barrier layer having a copper diffusion of about 300 Å or less.

10. A method of claim 1, wherein reacting the silicon and the carbon comprises reacting the silicon and the carbon while maintaining a chamber pressure between about 6 to about 10 Torr.

11. A method of claim 1, wherein reacting the silicon and the carbon comprises reacting the silicon and the carbon using an RF power supply supplying a power density of about 4.3 to about 10.0 watts per square centimeter to an anode and cathode in the chamber.

12. A method of claim 1, wherein providing the silicon comprises providing a silane flow rate of between about 10 to about 1000 sccm and providing the noble gas comprises providing a helium or argon flow rate of between about 50 to about 5000 sccm.

13. A method of claim 1, wherein providing the silicon, the carbon, and the noble gas comprises providing a methylsilane flow rate of between about 30 to about 500 sccm as the silicon and carbon source and a helium or argon gas flow rate of between about 100 to 2000 sccm as the noble gas source and further comprising reacting the silicon and the carbon in a chamber pressure range of about 3 to about 10 Torr with an RF power source supplying a power density of about 4.3 to about 10.0 watts per square centimeter to an anode and cathode in the chamber and a substrate surface temperature of between about 200° to about 400° C. and having a showerhead to substrate surface spacing of between about 300 to about 600 mils.

14. A method of claim 1, wherein the silicon carbide barrier layer comprises an etch selectivity ratio of at least about 40 to 1.

15. A method of forming a silicon carbide passivation layer on a substrate, comprising:
a) introducing silicon, carbon, and a noble gas into a chamber;
b) initiating a plasma in the chamber;
b) reacting the silicon and the carbon in the presence of the plasma to form silicon carbide; and
c) depositing a silicon carbide passivation layer on the substrate in the chamber.

16. A method of claim 15, wherein the silicon and carbon comprise a methylsilane.

17. A method of claim 15, further comprising depositing the silicon carbide barrier layer at a temperature of between about 300° to about 400° C.

18. A method of claim 15, wherein reacting the silicon and the carbon comprises reacting the silicon and the carbon using a chamber pressure between about 6 to about 8 Torr.

19. A method of claim 15, further comprising producing a silicon carbide passivation layer having no substantial penetration of moisture.

20. A method of claim 15, wherein reacting the silicon and the carbon comprises reacting the silicon and the carbon using an RF power supply supplying a power density of about 8.6 to about 14.3 watts per square centimeter to an anode and cathode in the chamber.

21. A method of claim 15, wherein providing the silicon, the carbon, and the noble gas comprises providing a methylsilane flow rate of between about 100 to about 500 sccm as the silicon and the carbon source and providing a helium or argon gas flow rate between about 1000 to about 2000 sccm as the noble gas source and further comprising reacting the silicon and the carbon in a chamber pressure range of about 6 to about 8 Torr with an RF power source supplying a power density of about 8.6 to about 14.3 watts per square centimeter to an anode and cathode in the chamber and a substrate temperature of between about 200° to about 400° C. and having a gas dispersion head to substrate spacing of between about 200 to about 600 mils.

22. A method of claim 15, wherein the silicon and carbon are derived from a common methylsilane, independent of other carbon sources.

23. A substrate having a silicon carbide layer, comprising:
a) a semiconductor substrate;
b) a dielectric layer deposited on the substrate; and
c) a silicon carbide layer having a dielectric constant of about 6 or less.

24. The substrate of claim 23, wherein the silicon carbide layer comprises an effective dielectric constant of about 3 or less.

25. The substrate of claim 23, wherein the silicon carbide layer comprises a copper diffusion of about 300 Å or less.

26. The substrate of claim 23, wherein the silicon carbide layer comprises an etch selectivity ratio of at least about 40 to 1.

27. The substrate of claim 23, wherein the silicon carbide layer is produced by the process of providing silicon, carbon, and a noble gas comprising providing a methylsilane flow rate of between about 30 to about 500 sccm as the silicon and carbon source and a helium or argon gas flow rate of between about 100 to 2000 sccm as the noble gas source and further comprising reacting the silicon and the carbon in a chamber pressure range of about 3 to about 10 Torr with an RF power source supplying a power density of about 4.3 to about 10.0 watts per square centimeter to an anode and cathode in the chamber and a substrate surface temperature of between about 200° to about 400° C. and having a showerhead to substrate surface spacing of between about 300 to about 600 mils.
